(19) United States
(12) Patent Application Publication
(10) Pub. No.: US 2010/0109053 A1
(43) Pub. Date: May 6, 2010

(54) SEMICONDUCTOR DEVICE HAVING INTEGRATED CIRCUIT WITH PADS COUPLED BY EXTERNAL CONNECTING COMPONENT AND METHOD FOR MODIFYING INTEGRATED CIRCUIT

(76) Inventors: Ching-Han Jan, Hsinchu City (TW); Yu-Hsin Lin, Taipei City (TW)

Correspondence Address: NORTH AMERICA INTELLECTUAL PROPERTY CORPORATION, P.O. BOX 506, MERRIFIELD, VA, 22116, US

(21) Appl. No.: 12/264,272

(22) Filed: Nov. 4, 2008

(51) Int. Cl. H01L 23/62; H01L 21/66

(52) U.S. Cl. 257/203; 438/10; 257/E23.001; 257/E21.531

(57) ABSTRACT

The present invention discloses a semiconductor device. The semiconductor device includes an integrated circuit and a connecting component. The integrated circuit includes a first pad; a second pad; a first current guiding circuit, coupled to the first pad and a first reference voltage, for selectively guiding a first specific electrical signal received from the first pad to the first reference voltage; and a second current guiding circuit, coupled to the second pad and a second reference voltage, for selectively guiding a second specific electrical signal received from the second pad to the second reference voltage; and the connecting component is external to the integrated circuit for coupling the first pad and the second pad.

### BACKGROUND

The present invention relates to a semiconductor device, and more particularly to a semiconductor device having an integrated circuit with pads coupled by an external connecting component, and a method for modifying an integrated circuit.

Normally, the main surface of a semiconductor die includes a plurality of bonding pads, and the bonding pads are positioned around edge(s) of the main surface of the semiconductor die, as shown in FIG. 1. FIG. 1 illustrates a main surface of a prior art semiconductor die. A plurality of bonding wires 110 are bonded to the plurality of bonding pads 120 respectively, for electrically coupling the external signals into the semiconductor die, such as power source, ground source, input signal, and output signal, etc. For each bonding pad coupled to the power/ground sources, which are power/ground pads, an Electrostatic Discharging (ESD) protection circuit always exists below the power/ground pad for protecting the semiconductor die from being damaged by the electrostatic signal. However, the fabrication process of the semiconductor die will not guarantee that each ESD protection circuit can work perfectly as desired. In other words, some ESD protection circuits may not respond fast enough to discharge the electrostatic signal induced to the corresponding pad. When this happens, there are two options for the semiconductor chip designer. The first is to redesign the ESD protection circuit of the semiconductor chip, and the second is to ignore the ESD protection circuit. The first option will prolong the fabricating time of the semiconductor chip and drastically increase the cost of the semiconductor chip. The second option may shorten the lifetime of the semiconductor chip, and more seriously, this will affect the normal operation of the semiconductor chip.

### SUMMARY OF THE INVENTION

Therefore, one of the objectives of the present invention is to provide a semiconductor device and method thereof for modifying an integrated circuit using a connecting component external to the integrated circuit to be modified.

According to an embodiment of the present invention, a semiconductor device is disclosed. The semiconductor device comprises an integrated circuit and a connecting component. The integrated circuit comprises a first pad; a second pad; a first current guiding circuit coupled to the first pad and a first reference voltage, for selectively guiding a first specific electrical signal received from the first pad to the first reference voltage; and a second current guiding circuit coupled to the second pad and a second reference voltage, for selectively guiding a second specific electrical signal received from the second pad to the second reference voltage. The connecting component is external to the integrated circuit for coupling the first pad and the second pad.

According to another embodiment of the present invention, a method for modifying an integrated circuit is disclosed. The integrated circuit comprises a first pad; a second pad; a first current guiding circuit coupled to the first pad and a first reference voltage, for selectively guiding a first specific electrical signal received from the first pad to the first reference voltage; and a second current guiding circuit coupled to the second pad and a second reference voltage, for selectively guiding a second specific electrical signal received from the second pad to the second reference voltage. The method comprises: providing a connection component; and utilizing the connection component to couple the first pad and the second pad, wherein the connection component is external to the integrated circuit.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a top view of a prior art semiconductor die.

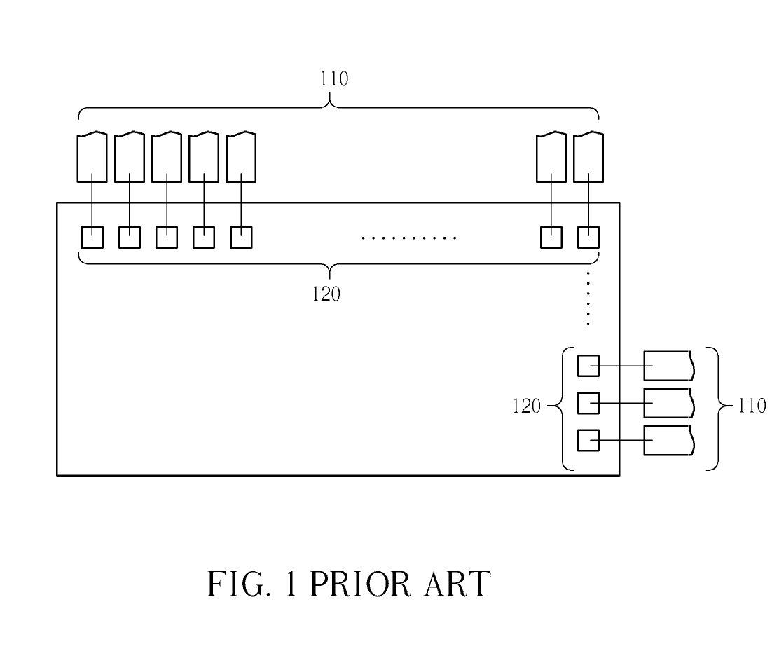

FIG. 2 is a top view of a semiconductor device according to an embodiment of the present invention.

FIG. 3 is a schematic circuit diagram illustrating the semiconductor device in FIG. 2.

FIG. 4 is a timing diagram illustrating a first specific electrical signal and a second specific electrical signal of FIG. 3.

FIG. 5 is a top view of an integrated circuit under test.

FIG. 6 is a flowchart of a method for modifying the integrated circuit shown in FIG. 5 according to an embodiment of the present invention.

### DETAILED DESCRIPTION

Certain terms are used throughout the description and following claims to refer to particular components. As one skilled in the art will appreciate, manufacturers may refer to a component by different names. This document does not intend to distinguish between components that differ in name but not function. In the following description and in the claims, the terms “include” and “comprise” are used in an open-ended fashion, and thus should be interpreted to mean “include, but not limited to . . . ”. Also, the term “couple” is intended to mean either an indirect or direct electrical connection. Accordingly, if one device is coupled to another device, that connection may be through a direct electrical connection, or through an indirect electrical connection via other devices and connections.

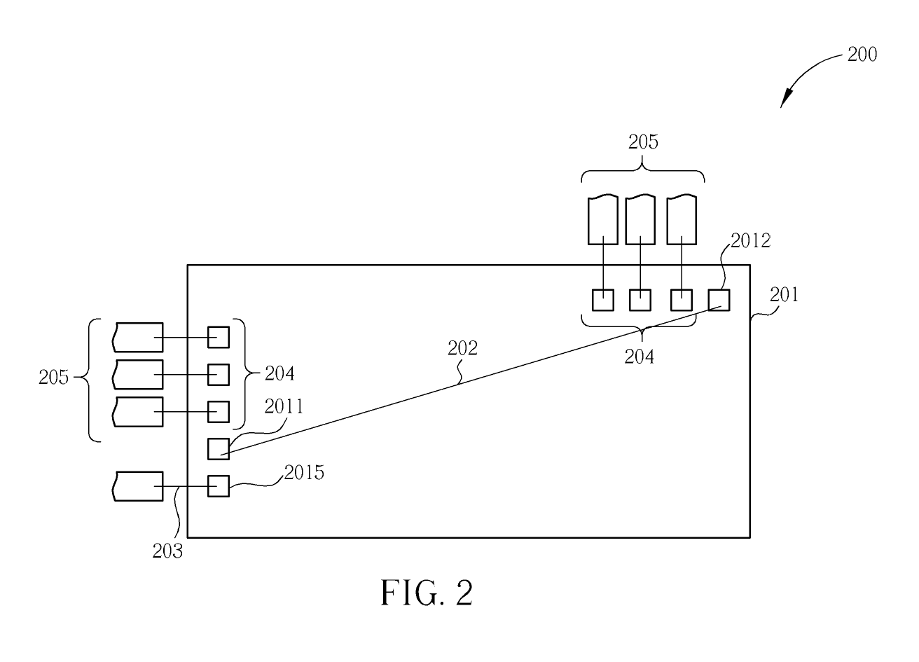

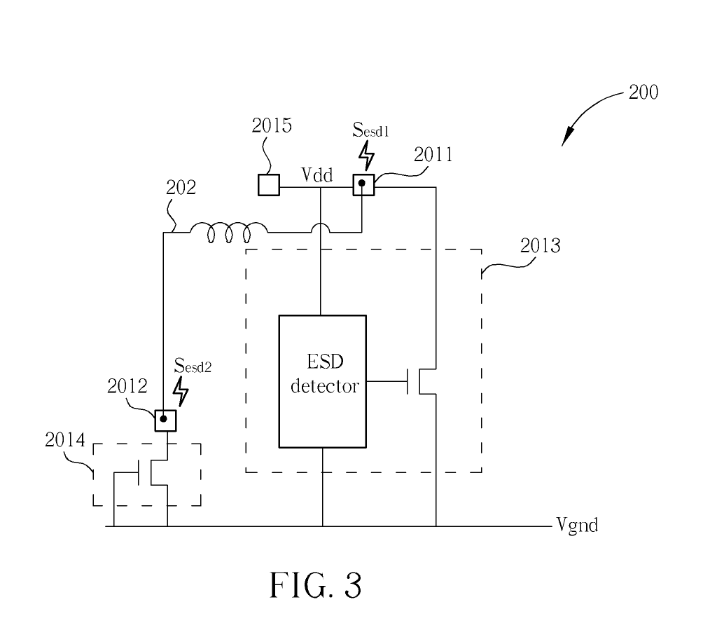

Please refer to FIG. 2 and FIG. 3 simultaneously. FIG. 2 is a top view of a semiconductor device 200 according to an embodiment of the present invention. FIG. 3 is a schematic circuit diagram illustrating the semiconductor device 200 shown in FIG. 2. The semiconductor device 200 comprises an integrated circuit 201 and at least a connecting component 202. It should be noted that only one connecting component is shown in FIG. 2 for simplicity. The integrated circuit 201 comprises a first pad 2011, a second pad 2012, a first current guiding circuit 2013, coupled to the first pad 2011 and a first reference voltage, for selectively guiding a first specific electrical signal S_{esd1} received from the first pad 2011 to the first reference voltage; and a second current guiding circuit 2014, coupled to the second pad 2012 and a second reference voltage, for selectively guiding a second specific electrical signal S_{esd2} received from the second pad 2012 to the second reference voltage. For brevity, the first reference voltage and the second reference voltage may be set to be the same ground voltage V_{gnd}, and the first pad 2011 and the second pad 2012 are coupled to the same power source V_{dd}. The connecting component 202, which can be an inner bonding wire, external to the integrated circuit 201, is for coupling the first pad 2011 and the second pad 2012. Please note that, in this embodiment, the first and second pads 2011, 2012 are power pads for receiving supply voltage or ground voltage; however, this is not meant to be a limitation of the present invention. In other words, the first and second pads 2011, 2012 can also be I/O pads for receiving/outputting signals. Furthermore, the first and second current guiding circuits 2013, 2014 may be implemented using an Electrostatic Discharge (ESD) protection circuit. Therefore, the first and second current guiding circuits 2013, 2014 are utilized to protect the first pad 2011 and the second pad 2012 from being damaged by induced electrostatics, which produce the first and second specific electrical signals S_{esd1}, S_{esd2} respectively.

Please refer to FIG. 2 again. The semiconductor device 200 further comprises a third pad 2015, a bonding wire 203, a plurality of pads 204, and a plurality of bonding wires 205. The bonding wire 203 is coupled to the third pad 2015 for receiving the power source V_{dd}. Furthermore, a conducting wire inside the semiconductor device 200 (not shown) is electrically coupled between the third pad 2015 and the second pad 2011. The pads 204 are coupled to the plurality of bonding wires 205 respectively. Please note that the functions of utilizing the plurality of pads 204 and the plurality of bonding wires 205 are known to those skilled in this art, thus a detailed description is omitted here for brevity. Additionally, the connecting component 202 may be equivalent to an inductive device, as shown in FIG. 3.

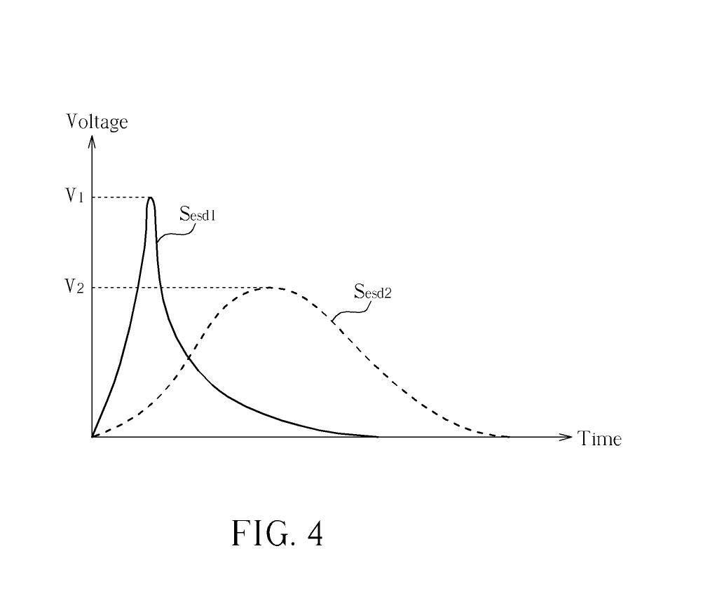

Please refer to FIG. 4. FIG. 4 is a timing diagram illustrating the first specific electrical signal S_{esd1} and the second specific electrical signal S_{esd2}. When the first specific electrical signal S_{esd1}, which is a rapidly increasing electrostatic signal (peak voltage V₁), is injected to the first pad 2011, the first current guiding circuits 2013 will be turned on to discharge the first specific electrical signal S_{esd1} to the ground voltage V_{gnd}. In addition, the inductive characteristic of the connecting component 202 will generate a large RC delay upon the first specific electrical signal S_{esd1}. When the first specific electrical signal S_{esd1} passes through the connecting component 202, it becomes the second specific electrical signal S_{esd2}. Accordingly, the second specific electrical signal S_{esd2} will be smoother (peak voltage V₂), as shown in FIG. 4. Then, the second specific electrical signal S_{esd2} will turn on the second current guiding circuit 2014 to discharge the second specific electrical signal S_{esd2} to the ground voltage V_{gnd}. In other words, there are two paths for the first specific electrical signal S_{esd1} to discharge; one is through the first current guiding circuit 2013, and the other is through the second pad 2012 and the second current guiding circuit 2014.

In order to describe the embodiment shown in FIG. 2 more clearly, the second current guiding circuit 2014 is a faulty ESD protection circuit that may be caused by the fabrication process of the semiconductor device 200. In other words, the functionality of the second current guiding circuit 2014 is not as perfect as the first current guiding circuit 2013. In a worst case, the second current guiding circuit 2014 has no ESD protection functionality. For example, in the ESD testing of Human Body Mode (HBM) and Machine Mode (MM), the second current guiding circuit 2014 fails the test at 1.5 KV and 250V, respectively. In other words, the second current guiding circuit 2014 can only respond to electrostatics that are below 1.5 KV and 250V of Human Body Mode and Machine Mode respectively. Accordingly, the connecting component 202 of the present invention is capable of buffering the first specific electrical signal S_{esd1} to become the second specific electrical signal S_{esd2}, which is smoother as shown in FIG. 4, and can be handled by the second current guiding circuit 2014.

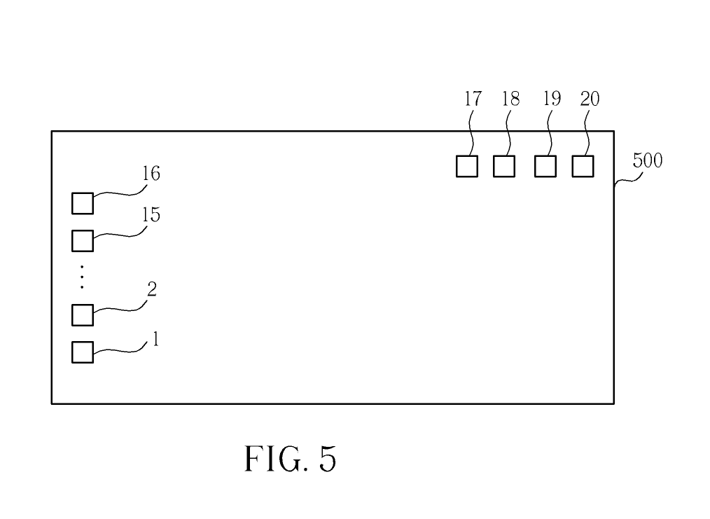

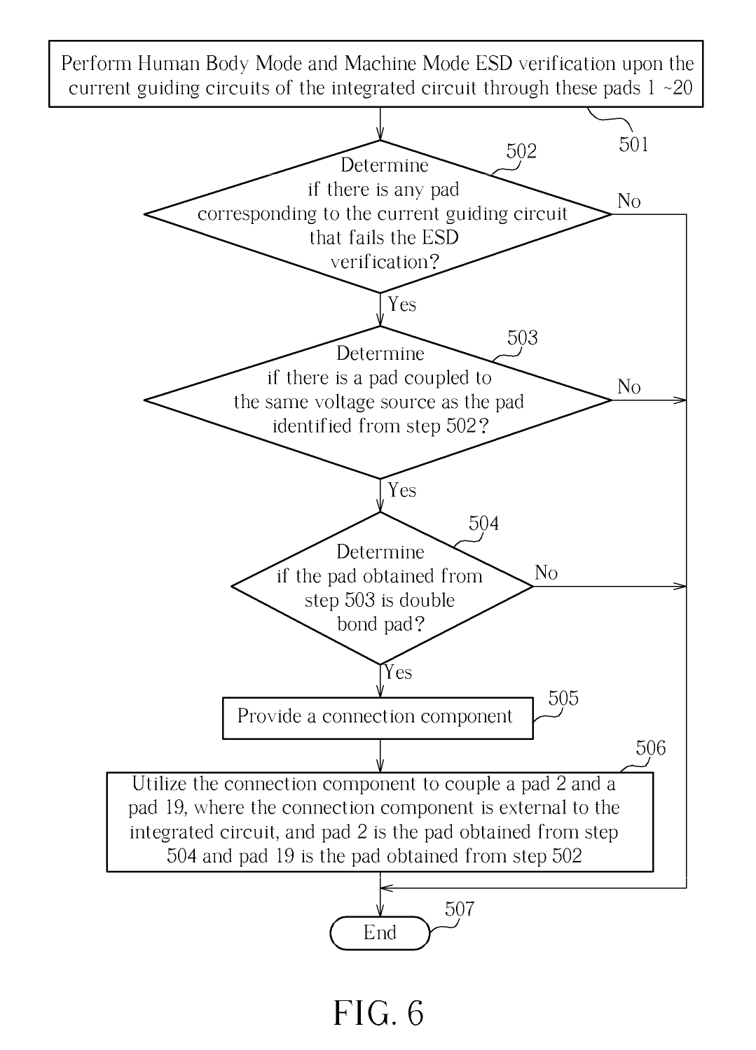

Please refer to FIG. 5 in conjunction with FIG. 6. FIG. 5 is a top view of an integrated circuit 500 under test. FIG. 6 is a flowchart of a method for modifying the integrated circuit 500 of FIG. 5. The integrated circuit 500 may be examined by Human Body Mode (HBM) and Machine Mode (MM) ESD testing. The integrated circuit 500 comprises a plurality of pads 120 and a plurality of current guiding circuits (not shown) coupled to the pads respectively, where each current guiding circuit is coupled to a corresponding pad and a corresponding reference voltage for guiding an electrical signal received from the corresponding pad to the corresponding reference voltage. Similar to the semiconductor device 200 of FIG. 2, the current guiding circuits are implemented with Electrostatic Discharge (ESD) protection circuits, and the electrical signal is an electrostatic signal. After the integrated circuit 500 has been fabricated, the method for modifying the integrated circuit 500 is performed to add the extra connecting component(s). Please note that if the result is substantially the same, the steps are not limited to be executed according to the exact order shown in FIG. 6. Besides, some step(s) may be omitted according to different applications. The method comprises the following steps:
Step 501: Perform Human Body Mode (HBM) and Machine Mode (MM) ESD verification upon the current guiding circuits of the integrated circuit 500 through these pads 120;
Step 502: Determine if there is any pad corresponding to the current guiding circuit that fails the ESD verification; if yes, go to 503; if no, go to 507;
Step 503: Determine if there is a pad coupled to the same voltage source (e.g. the supply voltage V_{dd}) as the pad identified from step 502; if yes, go to 504; if no, go to 507;
Step 504: Determine if the pad obtained from step 503 is a double bond pad; if yes, go to step 505; if no, go to 507;
Step 505: Provide a connection component;
Step 506: Utilize the connection component to couple a pad 2 and a pad 19, where the connection component is external to the integrated circuit, pad 2 is the pad obtained from step 504 and pad 19 is the pad obtained from step 502;
Step 507: End.

Before the bond wire is bonded to each pad of the integrated circuit 500, the integrated circuit 500 may be examined using the Human Body Mode (HBM) and Machine Mode (MM) ESD verification to verify the functionality of the current guiding circuits (step 501). If a pad (e.g. pad 19) is verified to fail the ESD verification at step 501, this means that the current guiding circuit coupled to the pad may fail at a specific voltage of the ESD verification, for example, at 1.5 KV and 250V of Human Body Mode (HBM) and Machine Mode (MM) respectively. Then, the flow will find out which pad that has passed the ESD verification has the same voltage source as the pad that has failed the ESD verification (step 503). If the pad that has passed the ESD verification is a double bond pad, such as pads 1 and 2, then a connection component is utilized to couple a pad 2 and a pad 19 (step 505, 506) to form the modified semiconductor device 200 as shown in FIG. 2. Therefore, according to the description of the embodiment of FIG. 2, the connecting component is capable of buffering the electro static signal at the pad 2 to transfer a smoother signal that can be handled by the current guiding circuit coupled to the pad 19.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor device, comprising:
an integrated circuit comprising:
a first pad;
a second pad;
a first current guiding circuit, coupled to the first pad and a first reference voltage, for selectively guiding a first specific electrical signal received from the first pad to the first reference voltage; and
a second current guiding circuit, coupled to the second pad and a second reference voltage, for selectively guiding a second specific electrical signal received from the second pad to the second reference voltage; and
a connecting component, external to the integrated circuit, for coupling the first pad and the second pad.

2. The semiconductor device of claim 1, wherein the first current guiding circuit is an Electro Static Discharge (ESD) protection circuit.

3. The semiconductor device of claim 2, wherein the first pad is a power/ground pad.

4. The semiconductor device of claim 2, wherein the first pad is an I/O pad.

5. The semiconductor device of claim 2, wherein the second current guiding circuit is an ESD protection circuit.

6. The semiconductor device of claim 5, wherein the first pad and the second pad are power/ground pads.

7. The semiconductor device of claim 5, wherein the first pad and the second pad are I/O pads.

8. The semiconductor device of claim 1, wherein the connection component is an inner bonding wire.

9. The semiconductor device of claim 8, wherein the inner bonding wire is directly connected between the first pad and the second pad.

10. A method for modifying an integrated circuit, the integrated circuit comprising:
a first pad;
a second pad;
a first current guiding circuit, coupled to the first pad and a first reference voltage, for selectively guiding a first specific electrical signal received from the first pad to the first reference voltage; and
a second current guiding circuit, coupled to the second pad and a second reference voltage, for selectively guiding a second specific electrical signal received from the second pad to the second reference voltage;
the method comprising:
providing a connection component; and
utilizing the connection component to couple the first pad and the second pad, wherein the connection component is external to the integrated circuit.

11. The method of claim 10, wherein the integrated circuit comprises a plurality of pads and a plurality of current guiding circuits coupled to the pads respectively, where each current guiding circuit is coupled to a corresponding pad and a corresponding reference voltage for guiding an electrical signal received from the corresponding pad to the corresponding reference voltage; and the step of utilizing the connection component to couple the first pad and the second pad comprises:
performing a verification upon the current guiding circuits; and
utilizing the connection component to connect the first pad to the second pad when the first current guiding circuit passes the verification and the second current guiding circuit fails the verification.

12. The method of claim 11, wherein the first current guiding circuit is an Electrostatic Discharge (ESD) protection circuit.

13. The method of claim 12, wherein the first pad is a power/ground pad.

14. The method of claim 12, wherein the first pad is an I/O pad.

15. The method of claim 12, wherein the second current guiding circuit is an ESD protection circuit.

16. The method of claim 15, wherein the first pad and the second pad are power/ground pads.

17. The method of claim 15, wherein the first pad and the second pad are I/O pads.

18. The method of claim 10, wherein the connection component is an inner bonding wire.

19. The method of claim 18, wherein the inner bonding wire is directly connected between the first pad and the second pad.
